(19) United States
(12) Patent Application Publication
(10) Pub. No.: US 2026/0150352 A1
(43) Pub. Date: May 28, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventor: Cheng-Wei LIU, Hsinchu (TW)

(21) Appl. No.: 19/088,873

(22) Filed: Mar. 24, 2025

Related U.S. Application Data
(60) Provisional application No. 63/724,944, filed on Nov. 26, 2024.

(51) Int. Cl. H10D 62/10; H01L 21/02; H10D 84/01; H10D 84/83

(52) U.S. Cl. CPC H10D 62/116; H10D 84/013; H10D 84/0151; H10D 84/8312; H10D 84/832; H10P 14/6339

(57) ABSTRACT

Embodiments of the present disclosure provide semiconductor device structures and methods of forming the same. The semiconductor device structure includes a plurality of semiconductor nanostructures, a gate stack surrounding each of the semiconductor nanostructures, a gate spacer extending along a sidewall of the gate stack, a first source/drain region electrically connected to a first semiconductor nanostructure of the plurality of semiconductor nanostructures, a semiconductor layer disposed below the first source/drain region, and a first dielectric layer disposed between the first source/drain region and the semiconductor layer. The first dielectric layer includes a first top surface that is concave and a first bottom surface that is substantial flat.

### CROSS-REFERENCE TO RELATED APPLICATIONS

This application claims priority to U.S. Provisional Application Ser. No. 63/724,944 filed Nov. 26, 2024, which is incorporated by reference in its entirety.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example stacking transistor in accordance with some embodiments.

FIGS. 2, 3, 4, 5, 6, 7, 7A, 8, 9, 10, 11, and 12 are views of intermediate stages in the manufacturing of a stacking transistor in accordance with some embodiments.

FIGS. 13, 14, 15, 16, and 17 are views of intermediate stages in the manufacturing of a stacking transistor in accordance with alternative embodiments.

FIGS. 18, 19, 20, and 21 are views of intermediate stages in the manufacturing of a stacking transistor in accordance with alternative embodiments.

FIGS. 22A, 22B, 22C, 22D, and 22E are views of intermediate stages in the manufacturing of a stacking transistor in accordance with alternative embodiments.

FIGS. 23A and 23B are views of intermediate stages in the manufacturing of a stacking transistor in accordance with alternative embodiments.

FIGS. 24A and 24B are views of intermediate stages in the manufacturing of a stacking transistor in accordance with alternative embodiments.

FIGS. 25, 26, 27, and 28 are views of intermediate stages in the manufacturing of a stacking transistor in accordance with alternative embodiments.

FIGS. 29, 30, and 31 are views of intermediate stages in the manufacturing of a stacking transistor in accordance with alternative embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor, such as a CFET, and the method of forming the same are provided. In various embodiments, the stacking transistor includes first and second dielectric layers disposed below and above a source/drain region of the bottom transistor. The first and/or second dielectric layer may have a shape that can prevent current leakage, prevent over etching of the source/drain region, and/or prevent air gap formation.

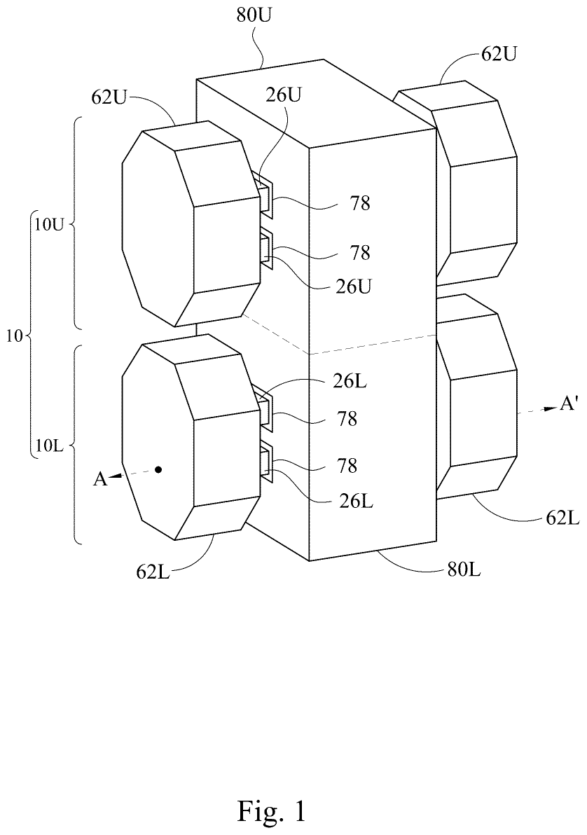

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. In this disclosure, a source region and a drain region are interchangeably used, and the structures thereof are substantially the same. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26 of the stacking transistor 10 and in a direction of, for example, a current flow between the source/drain regions 62 of the stacking transistor 10.

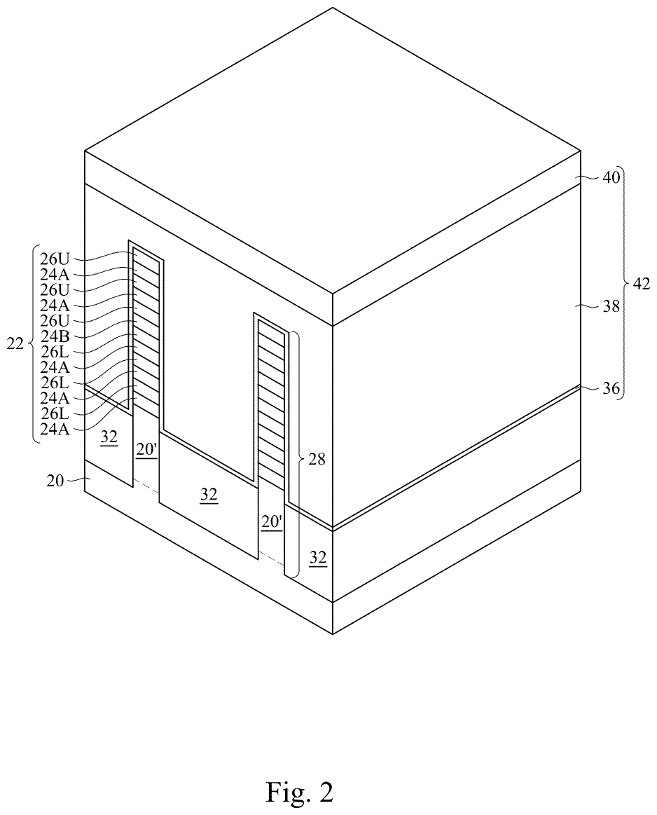

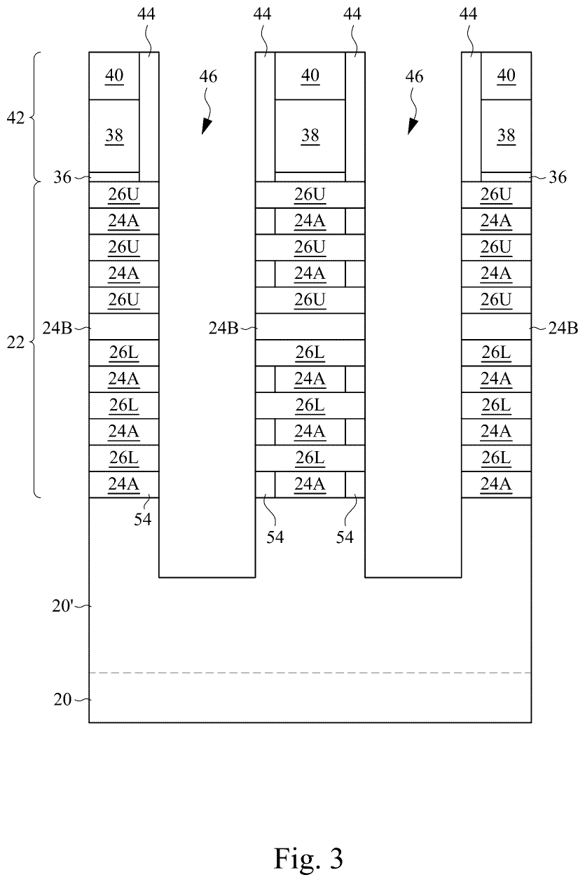

FIGS. 2 through 12 illustrate varying views of intermediate stages in the formation of stacking transistors (as schematically represented in FIG. 1) in accordance with some embodiments. FIG. 2 illustrates a perspective view similar to FIG. 1. FIGS. 3-12 illustrate cross-sectional views along a similar cross-section as reference cross-section A-A′ in FIG. 1.

In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof. In some embodiments, each of the substrate 20 may include an embedded CMP stop layer (not separately illustrated), such as a layer of silicon germanium embedded (e.g., sandwiched) between silicon material layers.

Semiconductor strips 28 are formed extending upwards from the semiconductor substrate 20. Each of semiconductor strips 28 includes semiconductor strip 20′ (patterned portions of the semiconductor substrate 20, also referred to as a semiconductor fin 20′) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructures 24 may be selectively removed in subsequent process steps without significantly removing the semiconductor nanostructures 26. In some embodiments, the dummy nanostructures 24A are formed of or comprise silicon germanium, the semiconductor nanostructures 26 are formed of silicon, and dummy semiconductor nanostructures 24B may be formed of germanium or silicon germanium with a higher germanium atomic percentage than the dummy nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor fins 20′, the dummy nanostructures 24, and the semiconductor nanostructures 26. The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, isolation regions 32, such as STI regions, are formed over the substrate 20 and between adjacent semiconductor strips 28. Isolation regions 32 may include a dielectric liner and a dielectric material over the dielectric liner. Each of the dielectric liner and the dielectric material may include an oxide such as silicon oxide, a nitride, such as silicon nitride, the like, or a combination thereof. In some embodiments, the k-value of the isolation region 32 ranges from about 3 to about 5. The formation of the isolation regions 32 may include depositing the dielectric layer(s) and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the isolation regions 32 include silicon oxide formed by an FCVD process, followed by an anneal process. Then, the dielectric layers(s) are recessed to define the isolation regions 32. The dielectric layer(s) may be recessed such that upper portions of semiconductor strips 28 (including multi-layer stacks 22) protrude higher than the remaining isolation regions 32. Although FIG. 2 illustrates a top surface of the isolation regions 32 as being flat, the top surface of the isolation regions 32 may be concave depending on the etching process used to recess the isolation regions 32.

After the isolation regions 32 are formed, dummy gate stacks 42 may be formed over and along sidewalls of the upper portions of the semiconductor strips 28 (the portions that protrude higher than the isolation regions 32). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20′. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth. In some embodiments, portions of the semiconductor strips 20′ are exposed at the bottom of the source/drain recesses 46, as shown in FIG. 3.

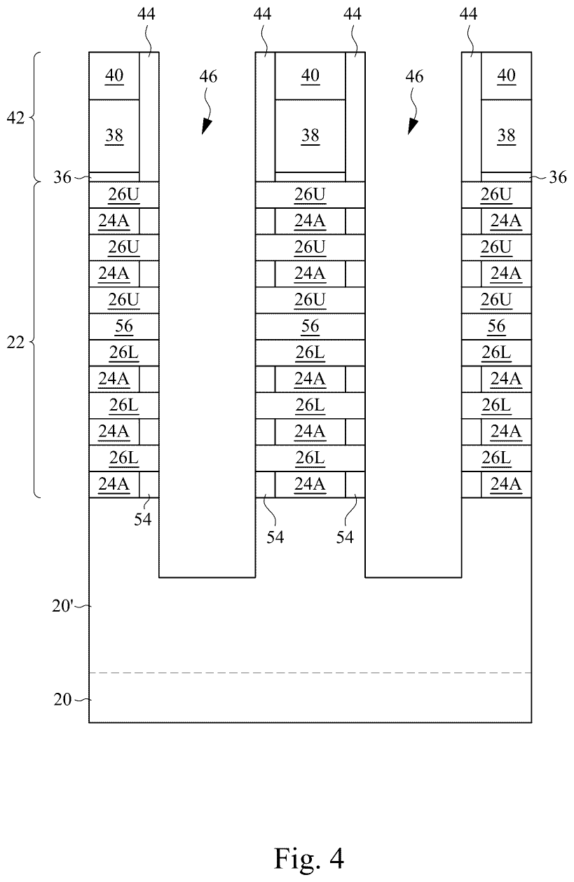

In FIG. 4, inner spacers 54 and dielectric isolation layers 56 are formed. Forming inner spacers 54 and dielectric isolation layers 56 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively).

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

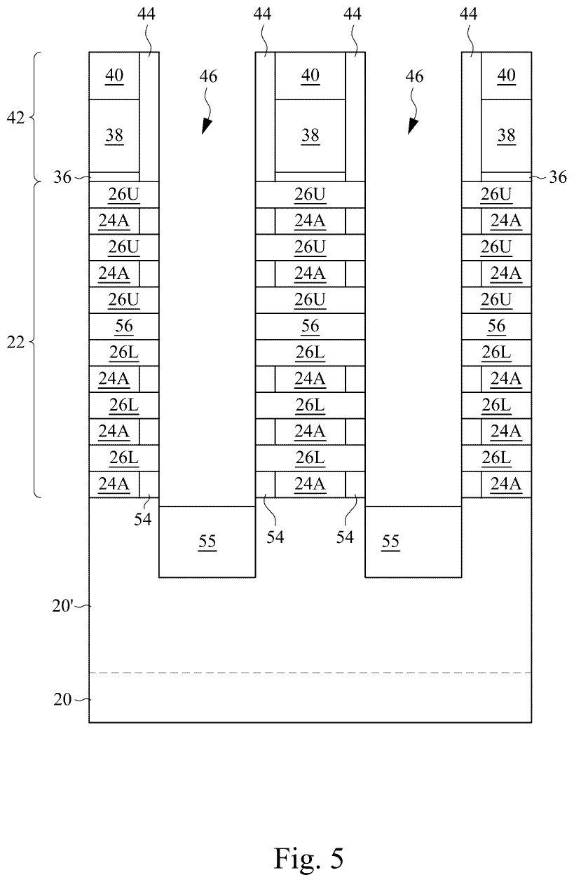

In FIG. 5, semiconductor layers 55 are formed at the bottom of the source/drain recesses 46. In some embodiments, the semiconductor layer 55 includes undoped silicon or undoped SiGe. In some embodiments, the term undoped may include materials being unintentionally doped. For example, the semiconductor layer 55 may contain dopant diffused from other regions. The semiconductor layers 55 may be first formed on semiconductor surfaces, such as on the exposed semiconductor strips 20′ and on the semiconductor nanostructures 26, by epitaxy. A subsequent etch process is performed to remove the portions of the semiconductor layer 55 formed on the semiconductor nanostructures 26. The top surface of the semiconductor layer 55 may be flat, as shown in FIG. 5. In some embodiments, the top surface of the semiconductor layer 55 is concave or convex, depending on the etch process to remove the portions of the semiconductor layer 55 formed on the semiconductor nanostructures 26.

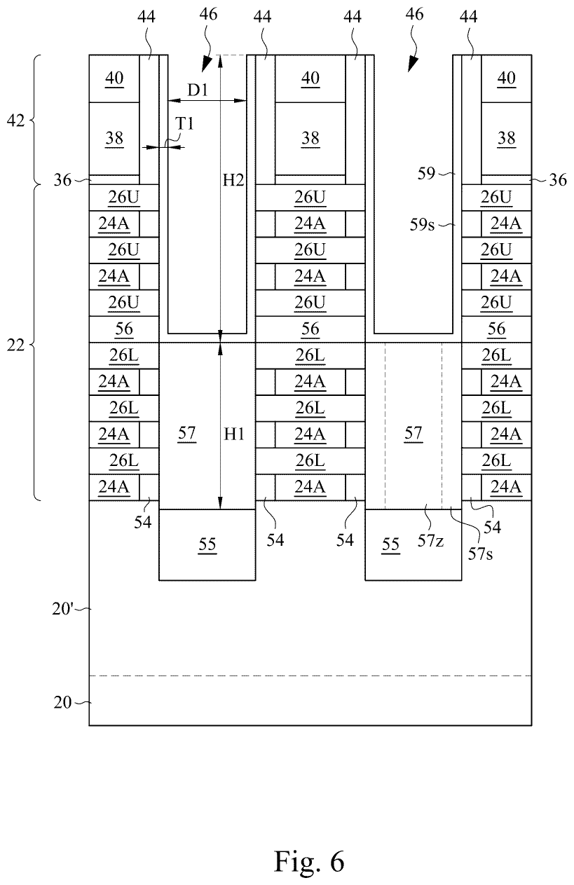

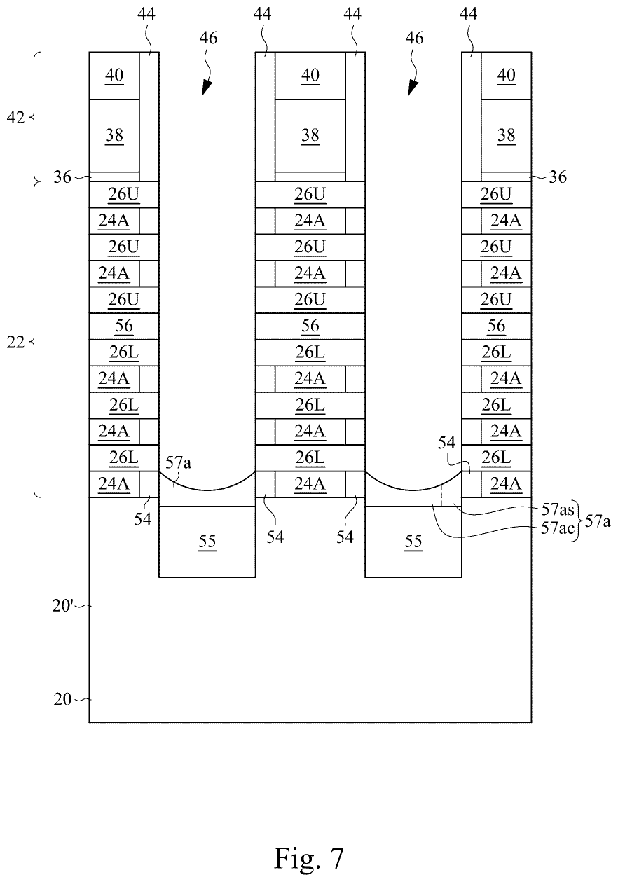

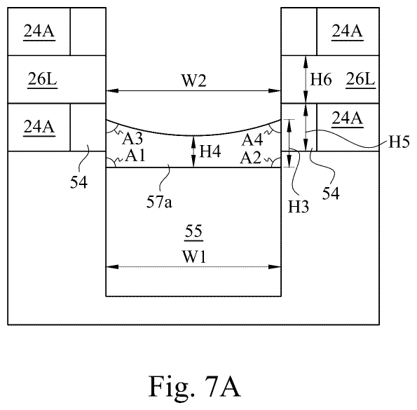

In FIG. 6, dielectric layers 57, 59 are formed in the source/drain recess 46 over the semiconductor layers 55. The dielectric layer 57 may be a dielectric material including Si, C, O, and/or N. For example, the dielectric layer 57 may be SiCN, SiON, SiN, SiCON, SiC, SiO, SiOC, or the like. The dielectric layer 59 may include a material selected from the same candidate group of materials for the dielectric layer 57. The dielectric layer 59 may include the same material as or different material from the dielectric layer 57. The dielectric layer 57 has a height H1, and the dielectric layer 59 has a height H2. In some embodiments, the dielectric layers 57, 59 include the same material, and the height H1 is greater than the height H2. For example, the dielectric layers 57, 59 both include SiN. In such embodiments, after performing multiple etch processes to remove the second dielectric layer 59 and to recess the first dielectric layer 57, the remaining dielectric layer 57a (FIG. 7) has a shape that reduces the risk of current leakage. The formation of the dielectric layer 57a is described below in detail.

In some embodiments, the dielectric layers 57, 59 include different materials or have different compositions, and the height H1 is less than the height H2. For example, the dielectric layer 57 includes SiN and the dielectric layer 59 includes SiO₂, or the dielectric layers 57, 59 both include SiOC, and the concentrations of carbon in the dielectric layers 57, 59 are different. In such embodiments, the remaining dielectric layer 57a (FIG. 7) can be also formed.

In some embodiments, the dielectric layer 57 is formed in a bottom-up fashion. For example, the dielectric layer 57 is formed using FCVD. An annealing process may be performed after the FCVD process to cure the dielectric layer 57. The dielectric layer 59 may be formed by any suitable process, such as ALD or CVD. In some embodiments, the dielectric layer 59 is a conformal layer and formed by a conformal process, such as ALD. The dielectric layer 59 may be also formed over the mask layer 40. The dielectric layer 59 has a thickness T1, and a distance D1 is between side surfaces of the dielectric layer 59 that are facing each other, as shown in FIG. 6. In some embodiments, the thickness T1 is about five percent to about 20 percent of the distance D1. If the thickness T1 is outside of the above-mentioned range, the shape of the first dielectric layer 57a (FIG. 7A) would be different.

In some embodiments, as shown in FIG. 6, the dielectric layer 59 includes side portions 59s formed along the sidewalls of the multi-layer stacks 22 and a bottom portion 59b connecting the side portions 59s. The dielectric layer 57 includes side portions 57s located directly below the side portions 59s of the dielectric layer 59 and a center portion 57z located between the two side portions 57s. The side portions 57s and the center portion 57z of the dielectric layer 57 may be defined by imaginary dashed lines, as shown in FIG. 6, and the side portions 57s and the center portion 57z are monolithic.

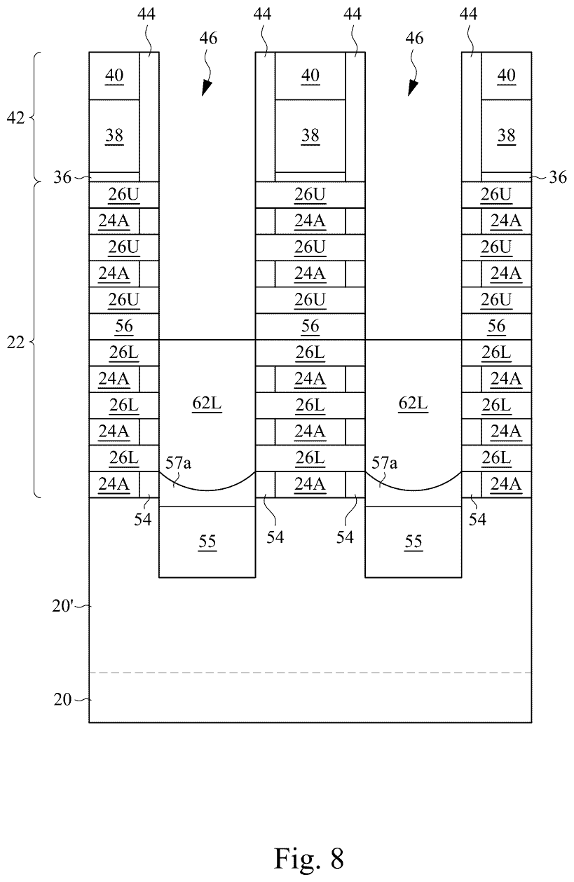

In FIG. 7, the dielectric layer 57a is formed after performing multiple etch processes. In some embodiments, a first etch process is performed to remove the bottom portion 59b of the dielectric layer 59 (FIG. 6) to expose the center portion 57z of the dielectric layer 57 (FIG. 6), and a second etch process is performed to remove the dielectric layer 59 and to recess the dielectric layer 57. For example, the first etch process may be an anisotropic etch process, such as a dry anisotropic etch process. The first etch process removes the bottom portion 59b of the dielectric layer 59, and the side portions 59s of the dielectric layer 59 formed along the multi-layer stacks 22 are substantially unaffected by the first etch process. The second etch process may be an isotropic etch process, such as a wet etch process. In some embodiments, the dielectric layers 57, 59 include the same material, and the second etch process etches the center portion 57z of the first dielectric layer 57, the side portions 59s of the dielectric layer 59, and the side portions 57s of the dielectric layer 57 at the same etch rate. Because the height H1 of the dielectric layer 57 is greater than the height H2 of the dielectric layer 59, the overall shape of the top surfaces of the dielectric layers 57, 59 may remain the same during the second etch process. As a result, the remaining dielectric layer 57a includes side portions 57as and a center portion 57ac, and the height of the side portions 57as is greater than the height of the center portion 57ac, as shown in FIG. 7. In some embodiments, the top surface of the dielectric layer 57a is concave. The dielectric layer 57a can function as a bottom isolation layer to prevent current leakage from subsequently formed source/drain regions 62L (FIG. 8) to the portion of the semiconductor strips 20′ located below the bottommost dummy nanostructure 24A. Thus, the increased height of the side portions 57as ensures that the portion of the semiconductor strips 20′ is not exposed, while the reduced height of the center portion 57ac can lead to larger source/drain region 62L, which in turn leads to reduced electrical resistance. In some embodiments, the side portions 57as at least partially in contact with the semiconductor strips 20′, as shown in FIG. 7.

In some embodiments, the dielectric layers 57, 59 include different materials, and the second etch process etches the center portion 57z of the dielectric layer 57, the side portions 59s of the dielectric layer 59, and the side portions 57s of the dielectric layer 57 at different etch rates. For example, the second etch process may utilize an etchant that removes the material of the dielectric layer 57 at a slower rate than the material of the dielectric layer 59. In some embodiments, hydrofluoric acid (HF) solution is used as the etchant. Because of the height H2 of the dielectric layer 59 is greater than the height H1 of the dielectric layer 57 and the side portions 59s are etched at a faster rate than the center portion 57z, the top surface of the dielectric layer 57 is concave after the removal of the side portions 59s of the dielectric layer 59. The shape of the top surface of the dielectric layer 57 remain unchanged as the dielectric layer 57 is recessed by the second etch process. As a result, the remaining dielectric layer 57a with the side portions 57as and the center portion 57ac are formed, as shown in FIG. 7.

In FIG. 7A, which is an enlarged view of a portion of the stacking transistor of FIG. 7, the dielectric layer 57a has an outer height H3 and an inner height H4 less than the outer height H3. In some embodiments, the outer height H3 ranges from about 3 nm to about 15 nm, and the inner height H4 ranges from about 1 nm to about 12 nm. As shown in FIG. 7A, the dielectric layer 57a has a top surface, a bottom surface, a first side surface connecting the top surface and the bottom surface, and a second side surface opposite the first side surface. An angle A1 is formed between the first side surface and the bottom surface, an angle A2 is formed between the bottom surface and the second side surface, an angle A3 is formed between the first side surface and the top surface, and an angle A4 is formed between the second side surface and the top surface. In some embodiments, the angle A1 ranges from about 75 degrees to about 100 degrees, the angle A2 ranges from about 75 degrees to about 100 degrees, the angle A3 ranges from about 30 degrees to about 60 degrees, and the angle A4 ranges from about 30 degrees to about 60 degrees. In some embodiments, the semiconductor layer 55 has a width W1, and the dielectric layer 57a has a width W2. The width W1 may be the same as the width W2. In some embodiments, the width W1 and the width W2 each ranges from about 10 nm to about 50 nm. As shown in FIG. 7A, the inner spacer 54 has a height H5, and the lower semiconductor nanostructures 26L has a height H6. In some embodiments, the height H5 ranges from about 3 nm to about 15 nm, and the height H6 ranges from about 3 nm to about 15 nm.

In some embodiments, the top surface of the semiconductor layer 55 is flat, and the bottom surface of the dielectric layer 57a is flat, as shown in FIG. 7A.

In FIG. 8, lower source/drain regions 62L are formed. The lower source/drain regions 62L are formed in the lower portions of the source/drain recesses 46. The lower source/drain regions 62L are in contact with the lower semiconductor nanostructures 26L and are not in contact with the upper semiconductor nanostructures 26U. Inner spacers 54 electrically insulate the lower source/drain regions 62L from the dummy nanostructures 24A, which will be replaced with replacement gates in subsequent processes.

The lower source/drain regions 62L are epitaxially grown and have a conductivity type that is suitable for the device type (p-type or n-type) of the lower nanostructure-FETs. When lower source/drain regions 62L are n-type source/drain regions, the respective material may include silicon or carbon-doped silicon, which is doped with an n-type dopant such as phosphorous, arsenic, or the like. When lower source/drain regions 62L are p-type source/drain regions, the respective material may include silicon or silicon germanium, which is doped with a p-type dopant such as boron, indium, or the like. The lower source/drain regions 62L may be in-situ doped, and may be, or may not be, implanted with the corresponding p-type or n-type dopants. During the epitaxy of the lower source/drain regions 62L, the lower source/drain regions 62L may be also formed on the upper semiconductor nanostructures 26U. A subsequent etch back process may be performed to remove the portion of the lower source/drain regions 62L formed on the upper semiconductor nanostructures 26U. The etch back process may stop when the top surface of the lower source/drain region 62L is at a level within a height of the dielectric isolation layer 56.

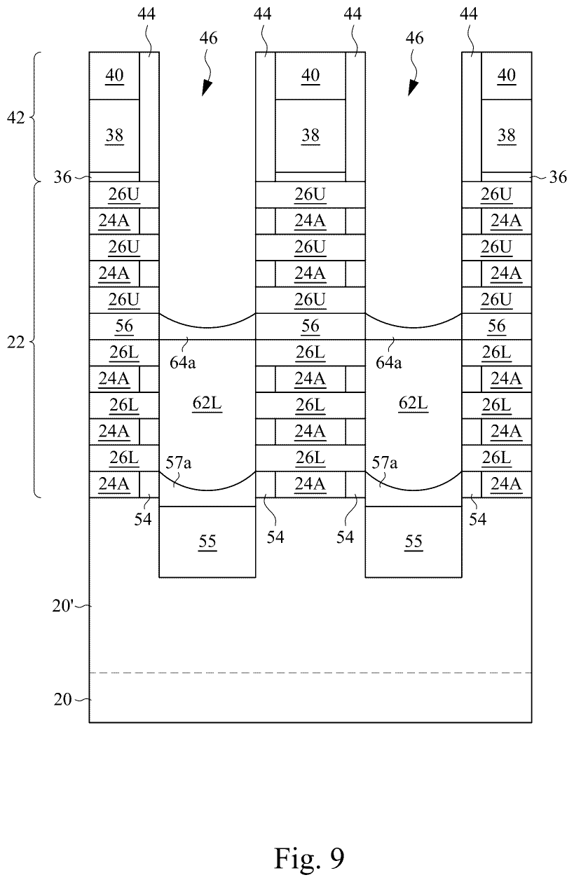

In FIG. 9, dielectric layers 64a are formed on the lower source/drain regions 62L. The dielectric layer 64a may include the same material as the dielectric layer 57a and may be formed by the same process as the dielectric layer 57a. The dielectric layer 64a electrically isolates the lower source/drain regions 62L and the subsequently formed upper source/drain regions 62U. Further, the dielectric layer 64a also electrically isolates the subsequently formed upper source/drain regions 62U and the topmost lower semiconductor nanostructure 26L. Thus, in some embodiments, the shape of the dielectric layer 64a is similar to the shape of the dielectric layer 57a, as shown in FIG. 9.

In some embodiments, the height of the dielectric layer 64a (e.g., the outer height of the second dielectric layer 64a) is less than the height of the dielectric isolation layer 56. As a result, the topmost lower semiconductor nanostructures 26L act as the channel regions for the lower nanostructure-FET 10L (FIG. 1), and the bottommost upper semiconductor nanostructures 26U act as the channel regions for the upper nanostructure-FET 10U (FIG. 1). In some embodiments, the highest height of the dielectric layer 64a is within the height of the dielectric isolation layer 56.

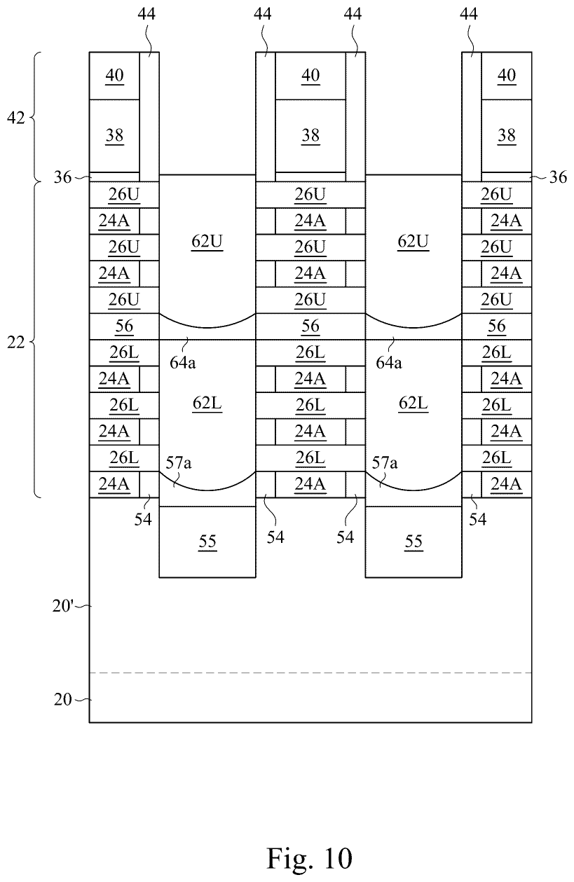

In FIG. 10, upper source/drain regions 62U are formed in the upper portions of the source/drain recesses 46. The upper source/drain regions 62U may be epitaxially grown from exposed surfaces of the upper semiconductor nanostructures 26U. The materials of upper source/drain regions 62U may be selected from the same candidate group of materials for forming lower source/drain regions 62L, depending on the desired conductivity type of upper source/drain regions 62U. The conductivity type of the upper source/drain regions 62U may be opposite the conductivity type of the lower source/drain regions 62L in embodiments where the stacking transistors are CFETs. For example, the upper source/drain regions 62U may be oppositely doped from the lower source/drain regions 62L. Alternatively, the conductivity types of the upper source/drain regions 62U and the lower source/drain regions 62L may be the same. The upper source/drain regions 62U may be in-situ doped, and/or may be implanted, with an n-type or p-type dopant.

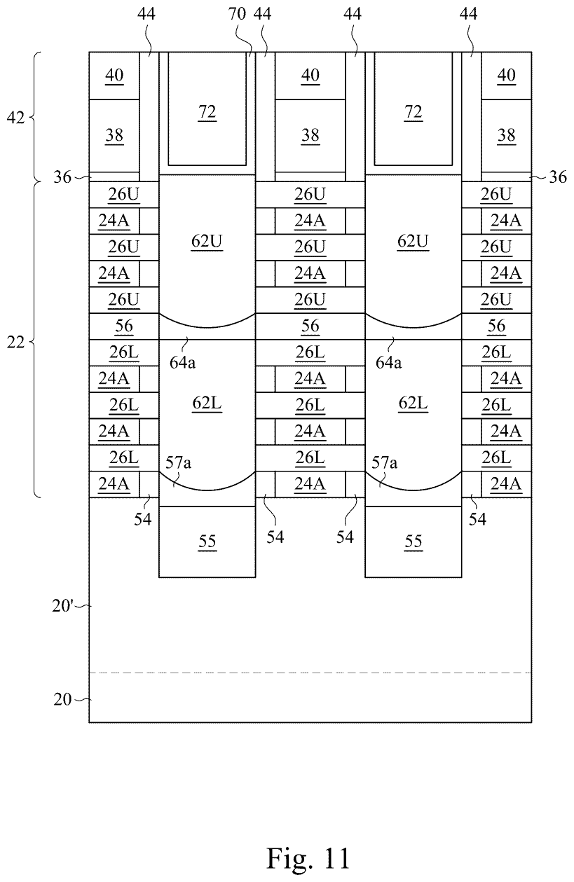

In FIG. 11, a contact etch stop layer (CESL) 70 and an interlayer dielectric (ILD) 72 are formed. The CESL 70 may be formed of a dielectric material having a high etching selectivity from the etching of the ILD 72, such as silicon nitride, silicon oxide, silicon oxynitride, or the like, which may be formed by any suitable deposition process, such as CVD, ALD, or the like. The ILD 72 may be formed of a dielectric material, which may be deposited by any suitable method, such as CVD, plasma-enhanced CVD (PECVD), or FCVD. The applicable dielectric material of the ILD 72 may include phospho-silicate glass (PSG), boro-silicate glass (BSG), boron-doped phospho-silicate glass (BPSG), undoped silicate glass (USG), silicon oxide, or the like. In some embodiments, the k-value of the ILD 72 ranges from about 3 to about 5.

The formation process may include depositing the layers for the CESL 70 and the ILD 72 and performing a planarization process to remove the excess portion of the corresponding layers. After the planarization process, top surfaces of the ILD 72, the gate spacers 44, and the masks 40 (if present) or the dummy gates 38 are substantially coplanar (within process variations). Accordingly, the top surfaces of the masks 40 (if present) or the dummy gates 38 are exposed through the ILD 72. In the illustrated embodiment, the masks 40 remain after the removal process. In other embodiments, the masks 40 are removed such that the top surfaces of the dummy gates 38 are exposed through the ILD 72.

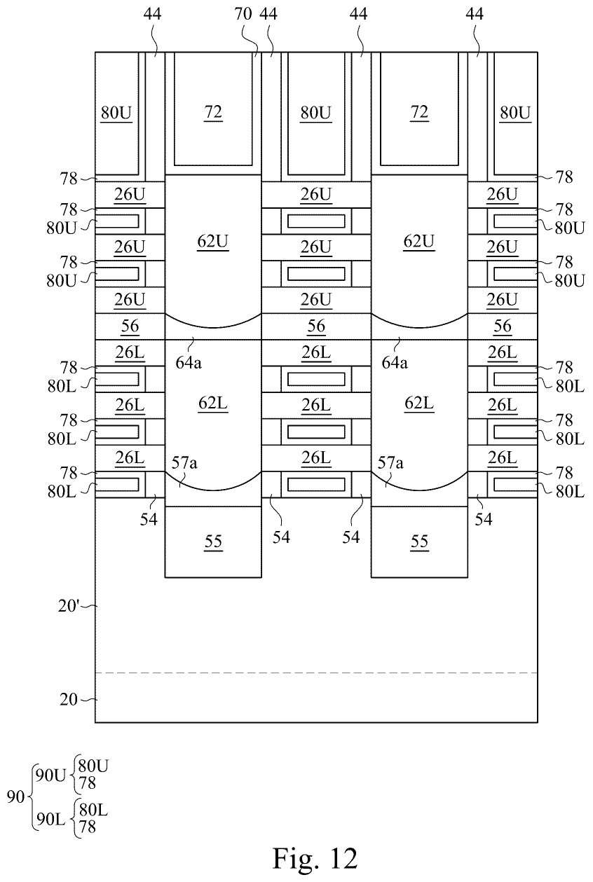

FIG. 12 illustrates a replacement gate process to replace the dummy gate stacks 42 and the dummy nanostructures 24A with gate stacks 90. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A is etched at a faster rate than the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed dummy gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor fins 20′; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD or other suitable methods. Although single-layered gate dielectrics 78 are illustrated, the gate dielectrics 78 may include multiple layers, such as an interfacial layer and an overlying high-k dielectric layer. In some embodiments, the k-value of the gate dielectric 78 is greater than a k-value of the gate spacer 44.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) and recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the ILD 72. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate stacks” 90 (including upper gate structures 90U and lower gate structures 90L).

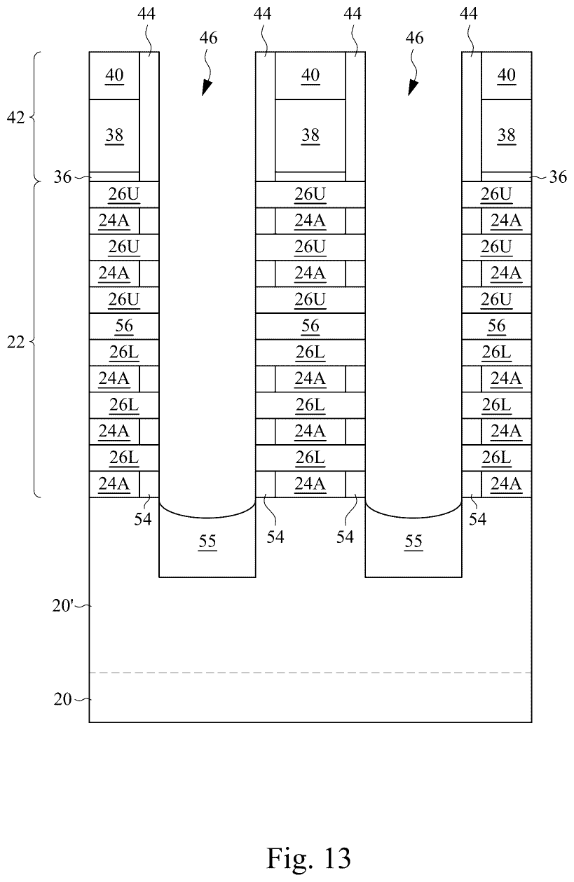

FIGS. 13, 14, 15, 16 and 17 are views of intermediate stages in the manufacturing of a stacking transistor in accordance with alternative embodiments. As shown in FIG. 13, in some embodiments, the top surface of the semiconductor layer 55 is concave as a result of the etch back process to remove the portions of the semiconductor layer 55 formed on the semiconductor nanostructures 26U, 26L. If the dielectric layer 57a (FIG. 7) is formed on the concave top surface of the semiconductor layer 55, the increased height of the side portions 57as of the dielectric layer 57a may cover the bottommost lower semiconductor nanostructure 26L. As a result, air gaps or voids may be formed in the lower source/drain regions 62L. Thus, in some embodiments, a dielectric layer having a different shape than the dielectric layer 57a is formed on the concave top surface of the semiconductor layer 55.

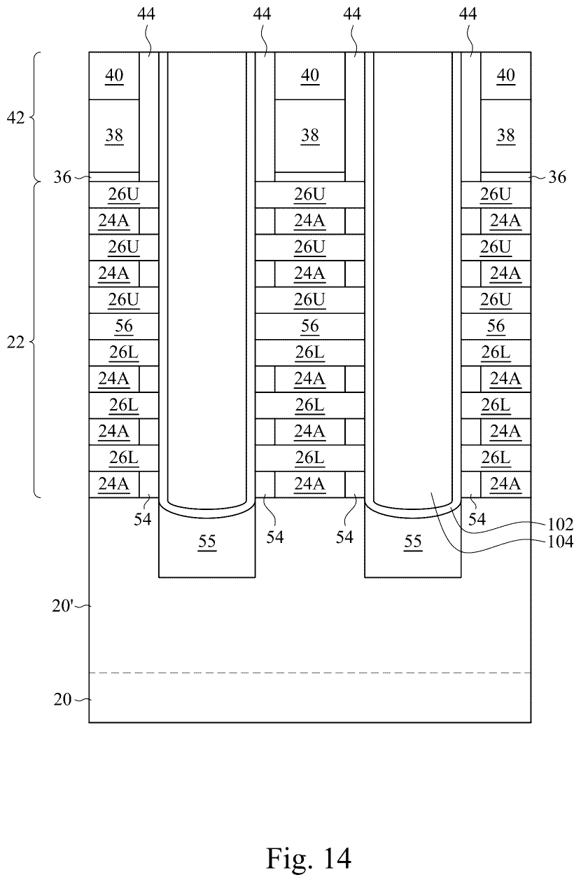

In FIG. 14, dielectric layers 102, 104 are formed in the source/drain recess 46 over the semiconductor layers 55. The dielectric layers 102, 104 may each include a material selected from the same candidate group of materials for the dielectric layer 57. The dielectric layer 102 may include a different material from the dielectric layer 104, or the dielectric layers 102, 104 include the same material but different compositions. For example, the dielectric layer 102 includes SiN and the dielectric layer 104 includes SiO₂, or the dielectric layers 102, 104 both include SiOC, and the concentrations of carbon in the dielectric layers 102, 104 are different.

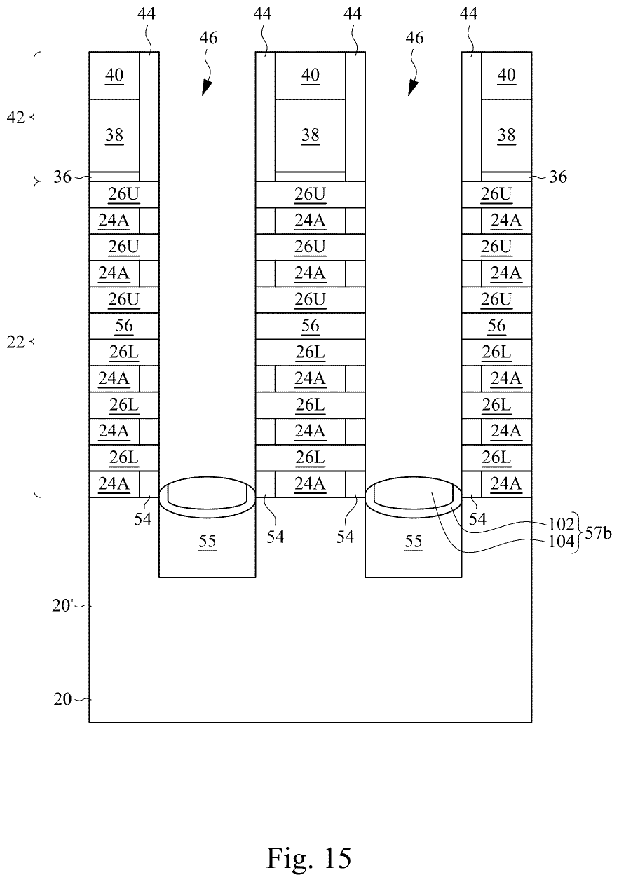

The dielectric layer 102 may be formed by any suitable process. In some embodiments, the dielectric layer 102 is a conformal layer and is formed by a conformal process, such as ALD. The dielectric layer 102 may be also formed over the mask 40. The dielectric layer 104 may be formed by any suitable process. In some embodiments, the dielectric layer 104 is formed by CVD, FCVD, or ALD. The dielectric layer 104 may be also formed over the mask 40. The portions of the first and second dielectric layers 102, 104 formed over the mask 40 may be removed by a planarization process, such as a CMP process. Next, one or more etch processes are performed to form the dielectric layer 57b (FIG. 15).

In FIG. 15, the dielectric layer 57b is formed after performing one or more etch processes. In some embodiments, a single etch process is performed to recess the dielectric layers 102, 104 to form the dielectric layer 57b. For example, the single etch process may be an isotropic etch process, such as a wet etch process, that utilizes an etchant that etches the dielectric layer 102 at a faster rate than the dielectric layer 104. In some embodiments, hydrofluoric acid (HF) solution is used as the etchant. The dielectric layer 57b has a convex top surface. For example, the convex top surface of the dielectric layer 57b includes top surfaces of the dielectric layers 102, 104, as shown in FIG. 15. Further, the height of the center portion of the dielectric layer 57b is greater than the height of the side portions of the dielectric layer 57b. As a result, the lowered height of the side portions of the dielectric layer 57b ensures the bottommost lower semiconductor nanostructures 26L are exposed, and the increased height of the center portion of the dielectric layer 57b prevents the formation of air gaps or voids in the lower source/drain regions 62L.

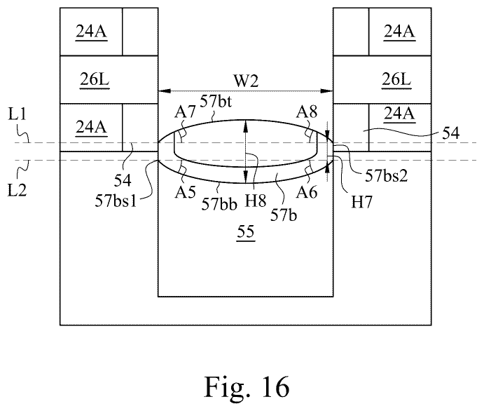

In FIG. 16, which is an enlarged view of a portion of the stacking transistor of FIG. 15, the dielectric layer 57b has an outer height H7 and an inner height H8 greater than the outer height H7. In some embodiments, the outer height H7 ranges from about 1 nm to about 10 nm, and the inner height H8 ranges from about 1 nm to about 15 nm. As shown in FIG. 16, the dielectric layer 57b has a top surface 57bt, a bottom surface 57bb, a first side surface 57bs1 connecting the top surface 57bt and the bottom surface 57bb, and a second side surface 57bs2 opposite the first side surface. The top surface 57bt, side surfaces 57bs1, 57bs2, and the bottom surface 57bb are defined by imaginary lines L1, L2. For example, the top surface 57bt is located over the imaginary line L1, the side surfaces 57bs1, 57bs2 are located between the imaginary lines L1, L2, and the bottom surface 57bb is located below the imaginary line L2. An angle A5 is formed between the first side surface 57bs1 and the imaginary line L2, an angle A6 is formed between the bottom surface 57bb and the imaginary line L2, an angle A7 is formed between the imaginary line L1 and the top surface 57bt, and an angle A8 is formed between the imaginary line L1 and the top surface 57bt. In some embodiments, the angles A5, A6, A7, and A8 each ranges from about 25 degrees to about 45 degrees. In some embodiments, the dielectric layer 57b has the width W2.

In some embodiments, the top surface of the semiconductor layer 55 is concave, and the bottom surface 57bb of the dielectric layer 57b is convex, as shown in FIG. 16.

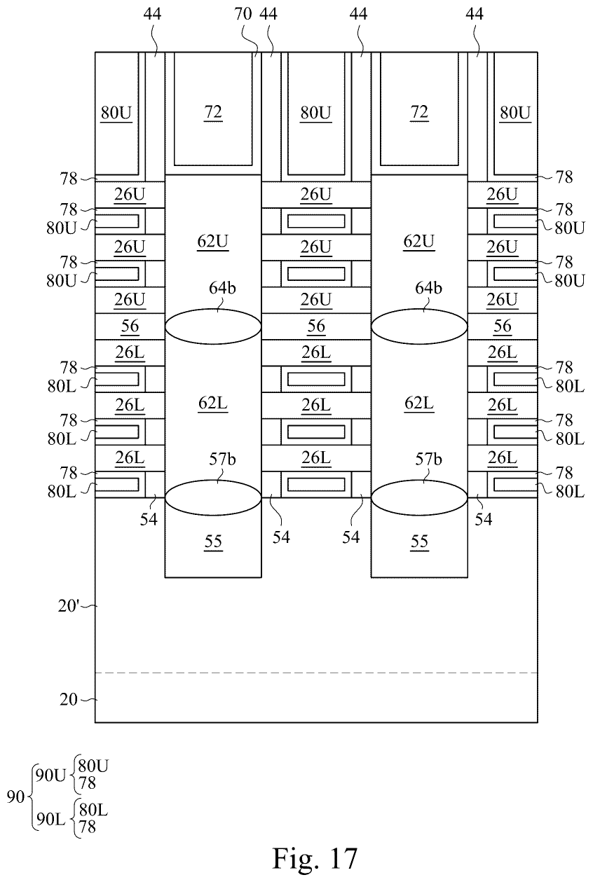

In FIG. 17, the lower source/drain regions 62L are formed over the dielectric layers 57b, and the top surface of the lower source/drain regions 62L may be concave as a result of the etch back process to remove portions of the lower source/drain regions 62L formed on the upper semiconductor nanostructures 26U. Thus, in some embodiments, in order to prevent current leakage and air gaps, dielectric layers 64b having the same shape as the dielectric layer 57b are formed on the concave top surface of the lower source/drain regions 62L, as shown in FIG. 17. For example, the reduced outer height of the dielectric layer 64b corresponds to the increased height of the side portions of the lower source/drain regions 62L. As a result, the bottommost upper semiconductor nanostructures 26U are not covered by the dielectric layer 64b. The increased inner height of the dielectric layer 64b corresponds to the reduced height of the center portion of the lower source/drain regions 62L. As a result, no air gaps are formed between the adjacent bottommost upper semiconductor nanostructures 26U.

Then, the upper source/drain regions 62U, the CESL 70, and the ILD 72 are formed over the dielectric layer 64b, and the replacement gate process is performed to replace the dummy gate stacks 42 and the dummy nanostructures 24A with gate stacks 90, as shown in FIG. 17.

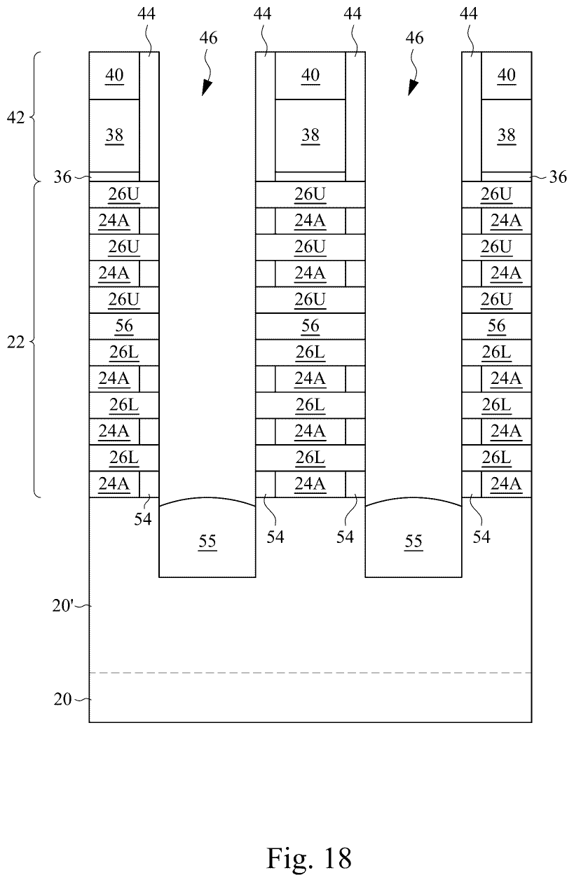

FIGS. 18, 19, 20, and 21 are views of intermediate stages in the manufacturing of a stacking transistor in accordance with alternative embodiments. As shown in FIG. 18, in some embodiments, the top surface of the semiconductor layer 55 is convex as a result of the deposition process to deposit the semiconductor layer 55 and the etch back process to remove the portions of the semiconductor layer 55 formed on the semiconductor nanostructures 26U, 26L. In such embodiments, dielectric layers 57c are formed on the convex top surface of the semiconductor layer 55. The dielectric layer 57c may include the same material as the dielectric layer 57a and may be formed by the same process as the dielectric layer 57a. For example, the concave top surface of the dielectric layer 57c may be a result of the processes described in FIG. 7 to form the dielectric layer 57a. The concave bottom surface of the dielectric layer 57c may be a result of the convex top surface of the semiconductor layer 55.

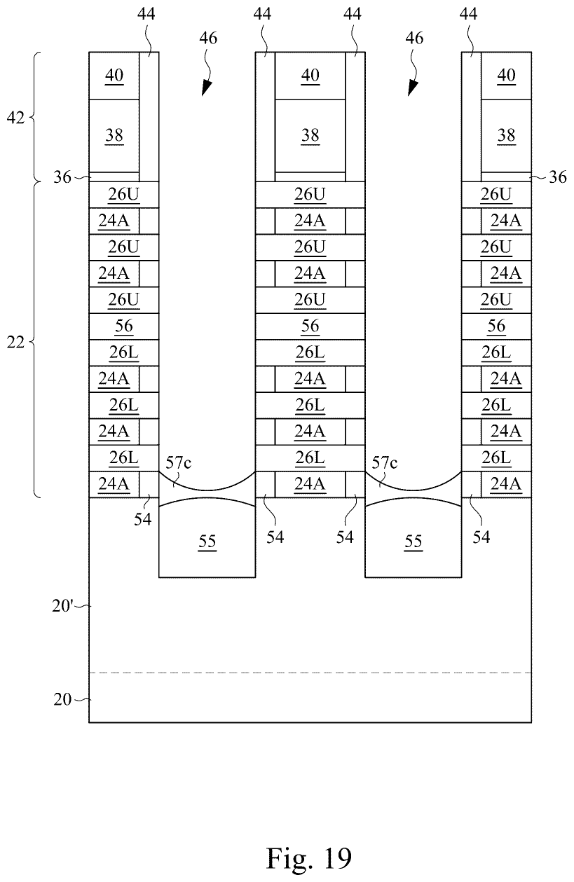

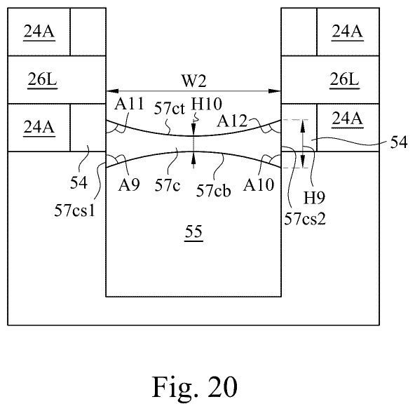

In FIG. 20, which is an enlarged view of a portion of the stacking transistor of FIG. 19, the dielectric layer 57c has an outer height H9 and an inner height H10 less than the outer height H9. In some embodiments, the outer height H9 ranges from about 1 nm to about 15 nm, and the inner height H10 ranges from about 1 nm to about 13 nm. As shown in FIG. 20, the dielectric layer 57c has a top surface 57ct, a bottom surface 57cb, a first side surface 57cs1 connecting the top surface 57ct and the bottom surface 57cb, and a second side surface 57cs2 opposite the first side surface 57cs1. An angle A9 is formed between the first side surface 57cs1 and the bottom surface 57cb, an angle A10 is formed between the bottom surface 57cb and the second side surface 57cs2, an angle A11 is formed between the first side surface 57cs1 and the top surface 57ct, and an angle A12 is formed between the second side surface 57cs2 and the top surface 57ct. In some embodiments, the angle A9 ranges from about 35 degrees to about 65 degrees, the angle A10 ranges from about 35 degrees to about 65 degrees, the angle A11 ranges from about 25 degrees to about 65 degrees, and the angle A12 ranges from about 25 degrees to about 65 degrees. In some embodiments, the dielectric layer 57c has the width W2.

In some embodiments, the top surface of the semiconductor layer 55 is convex, and the bottom surface 57cb of the dielectric layer 57c is concave, as shown in FIG. 20.

As shown in FIG. 20, the increased outer height H9 of the dielectric layer 57c corresponds to the lowered height of the edge portion of the semiconductor layer 55. As a result, the portion of the semiconductor strip 20′ located below the bottommost dummy nanostructure 24A is covered by the dielectric layer 57c. The lowered inner height H10 of the dielectric layer 57c corresponds to the increased height of the center portion of the semiconductor layer 55. As a result, the size of the lower source/drain regions 62L is not reduced.

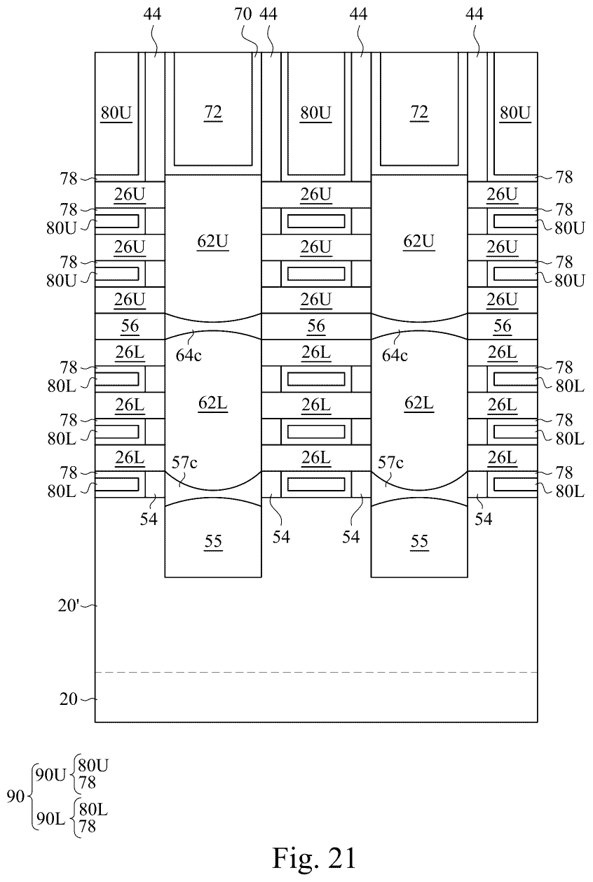

In FIG. 21, the lower source/drain regions 62L are formed over the dielectric layers 57c, and the top surface of the lower source/drain regions 62L may be convex as a result of the deposition process to deposit the lower source/drain regions 62L and the etch back process to remove portions of the lower source/drain regions 62L formed on the upper semiconductor nanostructures 26U. Thus, in some embodiments, in order to prevent current leakage, dielectric layers 64c having the same shape as the dielectric layer 57c are formed on the convex top surface of the lower source/drain regions 62L, as shown in FIG. 21. For example, the increased outer height of the dielectric layer 64c corresponds to the reduced height of the side portions of the lower source/drain regions 62L. As a result, the upper source/drain regions 62U are not in contact with the topmost lower semiconductor nanostructures 26L. The reduced inner height of the dielectric layer 64c corresponds to the increased height of the center portion of the lower source/drain regions 62L. As a result, the size of the upper source/drain regions 62U is not reduced.

Then, the upper source/drain regions 62U, the CESL 70, and the ILD 72 are formed over the dielectric layer 64c, and the replacement gate process is performed to replace the dummy gate stacks 42 and the dummy nanostructures 24A with gate stacks 90, as shown in FIG. 21.

In some embodiments, the dielectric layer 57a, 57b, or 57c may be placed between the semiconductor layer 55 and the bottom source/drain region 62L based on the shape of the semiconductor layer 55. For example, if the top surface of the semiconductor layer 55 is concave, the dielectric layer 57b may be used. If the top surface of the semiconductor layer 55 is convex, the dielectric layer 57c may be used. If the top surface of the semiconductor layer 55 is flat, the dielectric layer 57a may be used. Similarly, in some embodiments, the dielectric layer 64a, 64b, or 64c may be placed between the lower source/drain region 62L and the upper source/drain region 62U based on the shape of the lower source/drain region 62L. For example, if the top surface of the lower source/drain region 62L is concave, the dielectric layer 64b may be used. If the top surface of the lower source/drain region 62L is convex, the dielectric layer 64c may be used. If the top surface of the lower source/drain region 62L is flat, the dielectric layer 64a may be used. Thus, the dielectric layers 57a, 57b, 57c, 64a, 64b, 64c may be mixed and matched to improve device performance.

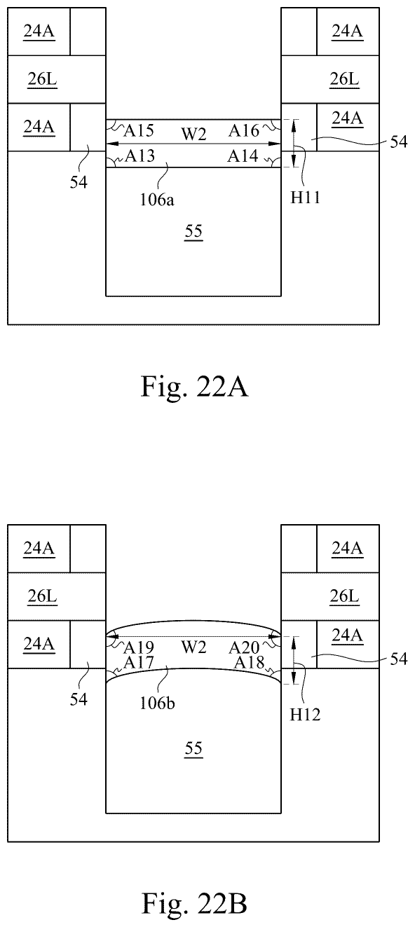

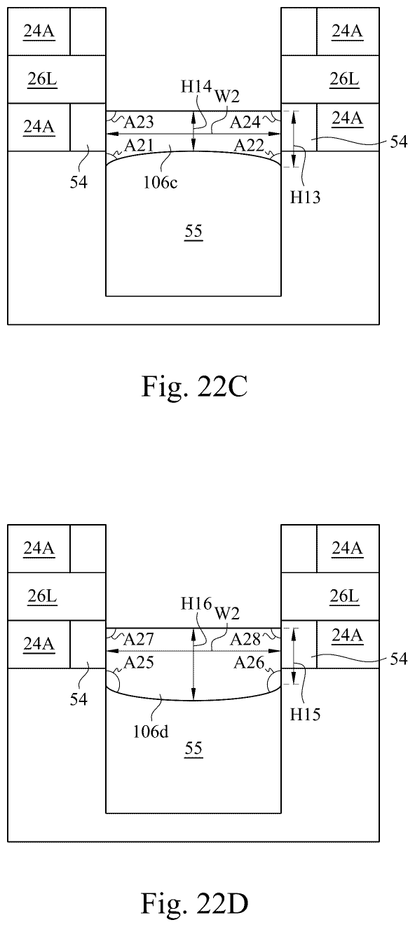

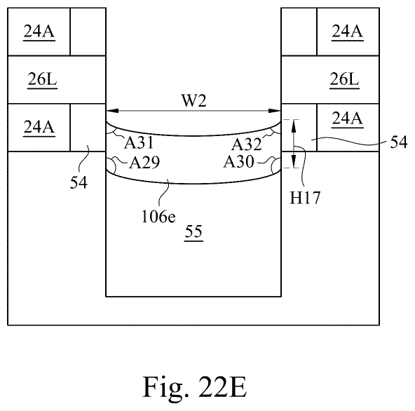

FIGS. 22A, 22B, 22C, 22D, and 22E are views of intermediate stages in the manufacturing of a stacking transistor in accordance with alternative embodiments. As shown in FIG. 22A, a dielectric layer 106a is formed on the semiconductor layer 55. In some embodiments, the top surface of the semiconductor layer 55 is flat, and the dielectric layer 106a is substantially conformal. The dielectric layer 106 a has a height H11 ranging from about 3 nm to about 15 nm. The dielectric layer 106a includes a top surface, a bottom surface, a first side surface connecting the top and bottom surfaces, and a second side surface opposite the first side surface. An angle A13 is formed between the first side surface and the bottom surface, an angle A14 is formed between the bottom surface and the second side surface, an angle A15 is formed between the first side surface and the top surface, and an angle A16 is formed between the second side surface and the top surface. In some embodiments, the angles A13, A14, A15, and A16 each ranges from about 80 degrees to about 100 degrees, such as about 90 degrees. In some embodiments, the dielectric layer 106a has the width W2.

As shown in FIG. 22B, a dielectric layer 106b is formed on the semiconductor layer 55. In some embodiments, the top surface of the semiconductor layer 55 is convex, and the top surface of the dielectric layer 106b is also convex. Thus, the bottom surface of the dielectric layer 106b is concave. In some embodiments, the top surface and the bottom surface of the dielectric layer 106b are substantially parallel, and the dielectric layer 106b has a height H12 ranging from about 1 nm to about 15 nm. The dielectric layer 106b includes a top surface, a bottom surface, a first side surface connecting the top and bottom surfaces, and a second side surface opposite the first side surface. An angle A17 is formed between the first side surface and the bottom surface, an angle A18 is formed between the bottom surface and the second side surface, an angle A19 is formed between the first side surface and the top surface, and an angle A20 is formed between the second side surface and the top surface. In some embodiments, the angles A17 and A18 each ranges from about 35 degrees to about 65 degrees, and the angles A19 and A20 each ranges from about 90 degrees to about 120 degrees. In some embodiments, the dielectric layer 106b has the width W2.

As shown in FIG. 22C, a dielectric layer 106c is formed on the semiconductor layer 55. In some embodiments, the top surface of the semiconductor layer 55 is convex, and the top surface of the dielectric layer 106c is flat. Thus, the bottom surface of the dielectric layer 106c is also flat. In some embodiments, the dielectric layer 106c has an outer height H13 ranging from about 3 nm to about 15 nm and an inner height H14 ranging from 1 nm to about 13 nm. The dielectric layer 106c includes a top surface, a bottom surface, a first side surface connecting the top and bottom surfaces, and a second side surface opposite the first side surface. An angle A21 is formed between the first side surface and the bottom surface, an angle A22 is formed between the bottom surface and the second side surface, an angle A23 is formed between the first side surface and the top surface, and an angle A24 is formed between the second side surface and the top surface. In some embodiments, the angles A21 and A22 each ranges from about 35 degrees to about 65 degrees, and the angles A23 and A24 each ranges from about 80 degrees to about 100 degrees, such as 90 degrees. In some embodiments, the dielectric layer 106c has the width W2.

As shown in FIG. 22D, a dielectric layer 106d is formed on the semiconductor layer 55. In some embodiments, the top surface of the semiconductor layer 55 is concave, and the top surface of the dielectric layer 106d is flat. Thus, the bottom surface of the dielectric layer 106d is convex. In some embodiments, the dielectric layer 106d has an outer height H15 ranging from about 1 nm to about 10 nm and an inner height H16 ranging from 1 nm to about 15 nm. The dielectric layer 106d includes a top surface, a bottom surface, a first side surface connecting the top and bottom surfaces, and a second side surface opposite the first side surface. An angle A25 is formed between the first side surface and the bottom surface, an angle A26 is formed between the bottom surface and the second side surface, an angle A27 is formed between the first side surface and the top surface, and an angle A28 is formed between the second side surface and the top surface. In some embodiments, the angles A25 and A26 each ranges from about 115 degrees to about 135 degrees, and the angles A27 and A28 each ranges from about 80 degrees to about 100 degrees, such as 90 degrees. In some embodiments, the dielectric layer 106d has the width W2.

As shown in FIG. 22E, a dielectric layer 106e is formed on the semiconductor layer 55. In some embodiments, the top surface of the semiconductor layer 55 is concave, and the top surface of the dielectric layer 106e is also concave. Thus, the bottom surface of the dielectric layer 106e is convex. In some embodiments, the top surface and the bottom surface of the dielectric layer 106e are substantially parallel, and the dielectric layer 106e has a height H17 ranging from about 1 nm to about 15 nm. The dielectric layer 106 e includes a top surface, a bottom surface, a first side surface connecting the top and bottom surfaces, and a second side surface opposite the first side surface. An angle A29 is formed between the first side surface and the bottom surface, an angle A30 is formed between the bottom surface and the second side surface, an angle A31 is formed between the first side surface and the top surface, and an angle A32 is formed between the second side surface and the top surface. In some embodiments, the angles A29 and A30 each ranges from about 115 degrees to about 135 degrees, and the angles A31 and A32 each ranges from about 25 degrees to about 45 degrees. In some embodiments, the dielectric layer 106e has the width W2.

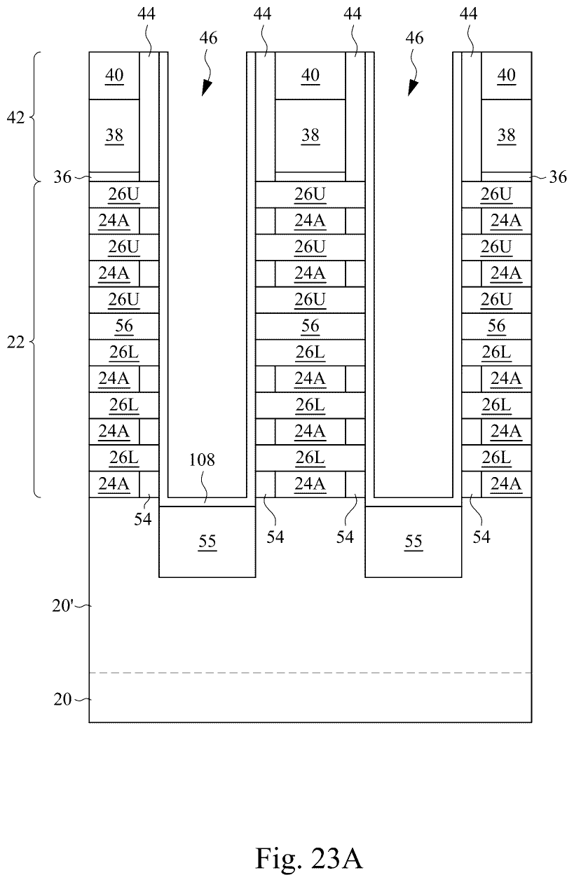

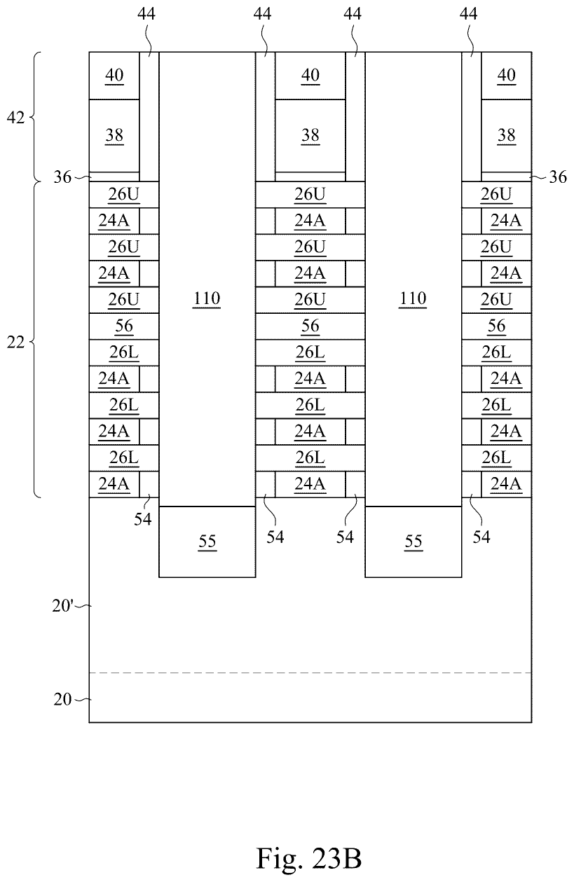

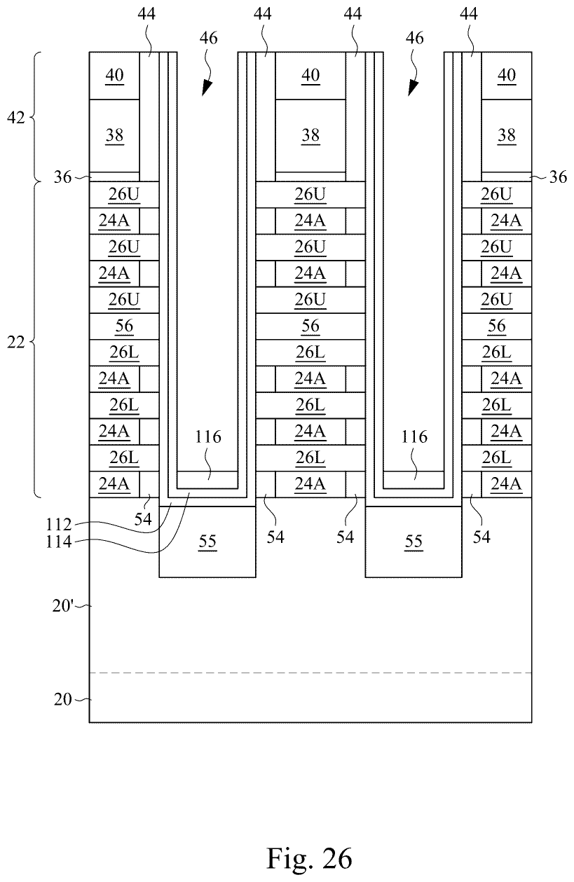

The dielectric layers 106a, 106b, 106c, 106d, and 106e may be used in the stacking transistor 10 (FIG. 1). The dielectric layers 106a, 106b, 106c, 106d, and 106e may be formed by any suitable process. For example, as shown in FIG. 23A, after forming the semiconductor layer 55, a dielectric layer 108 is formed on the semiconductor layers 55 in the source/drain recesses 46. The dielectric layer 108 may include the same material as the dielectric layer 57. In some embodiments, the dielectric layer 108 is a conformal layer formed by a conformal process, such as ALD. One or more etch processes, such as a dry etch process, a wet etch process, or combinations thereof, may be performed on the dielectric layer 108 to form the dielectric layers 106a, 106b, 106c, 106d, or 106e. In some embodiments, a sacrificial layer, such as the sacrificial layer 116 (FIG. 26), may be utilized to assist with the formation of the dielectric layers 106a, 106b, 106c, 106d, or 106e. In some embodiments, the dielectric layers 57a, 57b, or 57c may be formed by performing one or more etch process on the dielectric layer 108 with or without the assistance of a sacrificial layer.

Alternatively, in some embodiments, as shown in FIG. 23B, after forming the semiconductor layer 55, a dielectric layer 110 is formed on the semiconductor layers 55 in the source/drain recesses 46. The dielectric layer 110 may include the same material as the dielectric layer 57. In some embodiments, the dielectric layer 110 fills the source/drain recesses 46. The dielectric layer 110 may be formed by any suitable process, such as CVD, PECVD, FCVD, or ALD. One or more etch processes, such as a dry etch process, a wet etch process, or combinations thereof, may be performed on the dielectric layer 110 to form the dielectric layers 106a, 106b, 106c, 106d, or 106e. In some embodiments, the dielectric layers 57a, 57b, or 57c may be formed by performing one or more etch process on the dielectric layer 110.

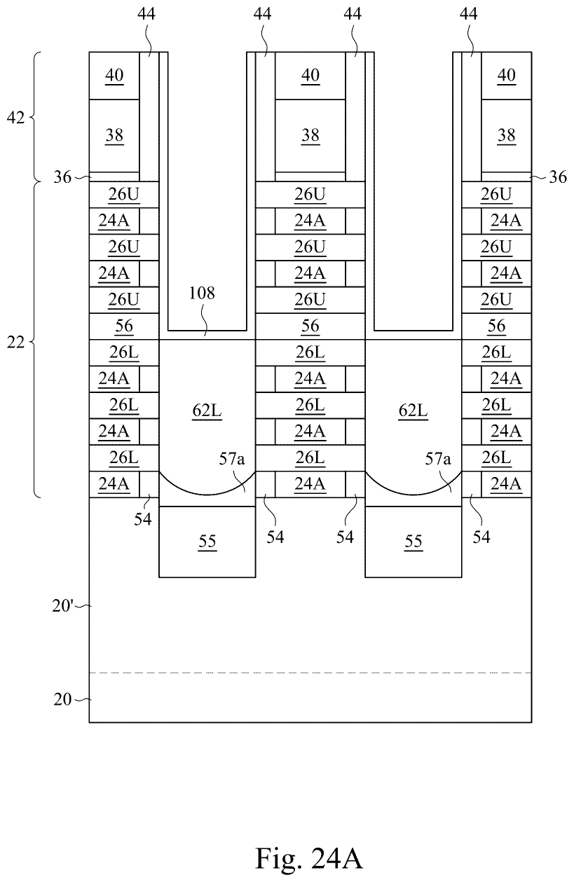

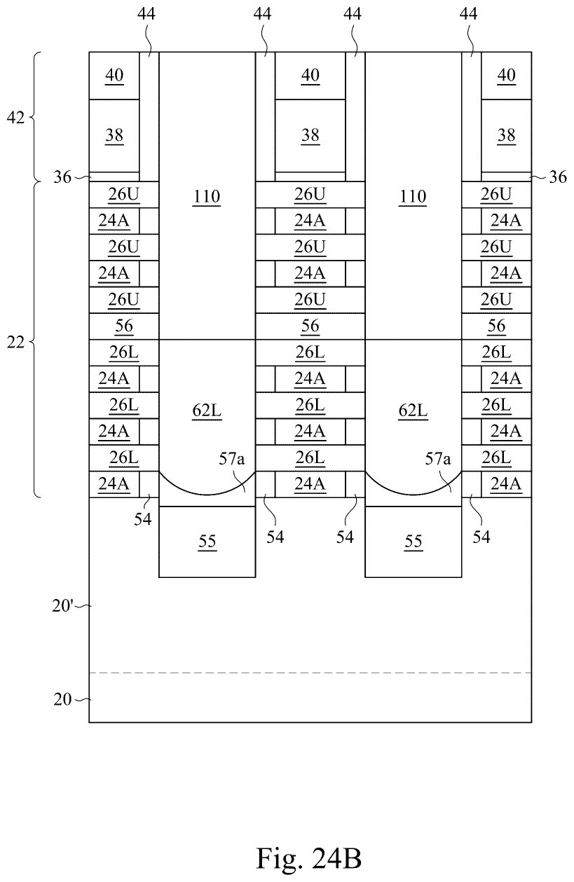

In some embodiments, the dielectric layers 106a, 106b, 106c, 106d, or 106e may be formed on the lower source/drain regions 62L, and the upper source/drain regions 62U are formed on the dielectric layers 106a, 106b, 106c, 106d, or 106e. In some embodiments, as shown in FIG. 24A, the dielectric layer 108 is formed on the lower source/drain regions 62L, and the one or more etch processes are performed on the dielectric layer 108 to form the dielectric layers 106a, 106b, 106c, 106d, or 106e on the lower source/drain regions 62L. Alternatively, in some embodiments, as shown in FIG. 24B, the dielectric layer 110 is formed on the lower source/drain regions 62L, and the one or more etch processes are performed on the dielectric layer 110 to form the dielectric layers 106a, 106b, 106c, 106d, or 106e on the lower source/drain regions 62L. Similar to the dielectric layers 57a, 57b, 57c, 64a, 64b, and 64c, the dielectric layers 106a, 106b, 106c, 106d, and 106e may be mixed and matched as the bottom dielectric layer located between the semiconductor layer 55 and the lower source/drain region 62L and the top dielectric layer located between the lower source/drain region 62L and the upper source/drain region 62U. Also similar to the dielectric layers 57a, 57b, 57c, 64a, 64b, 64c, the dielectric layers 106a, 106b, 106c, 106d, and 106e may prevent current leakage, prevent over etching of the source/drain region, and/or prevent air gap formation.

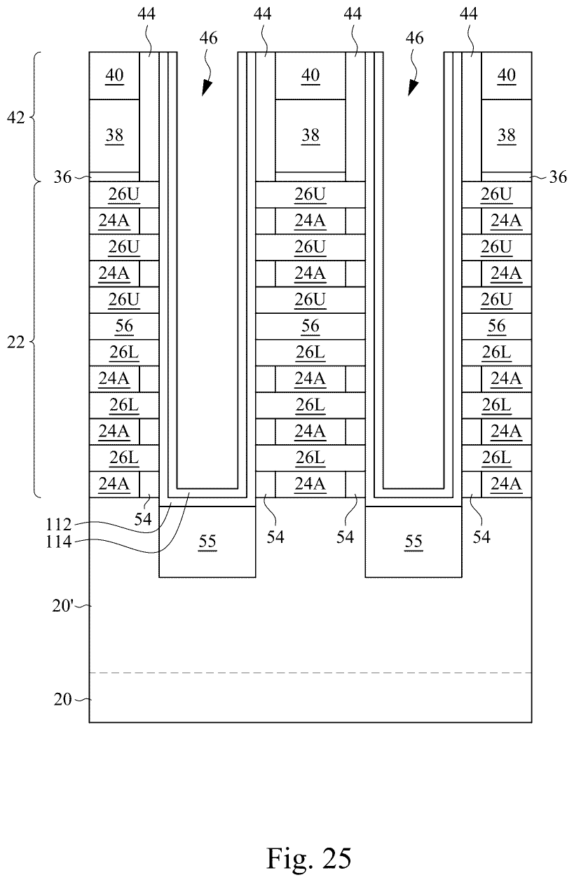

FIGS. 25, 26, 27, and 28 are views of intermediate stages in the manufacturing of a stacking transistor in accordance with alternative embodiments. In some embodiments, multiple dielectric layers are placed between the semiconductor layer 55 and the lower source/drain region 62L. For example, as shown in FIG. 25, a first dielectric layer 112 is formed in the source/drain recesses 46, and a second dielectric layer 114 is formed on the first dielectric layer 112. In some embodiments, the first and second dielectric layers 112, 114 have different k-values and etch selectivities. For example, the first dielectric layer 112 has a higher k-value and is etched at a slower rate compared to the second dielectric layer 114 during a subsequent etch process. In some embodiments, the first dielectric layer 112 and the second dielectric layer 114 include materials selected from the same candidate group of materials for the dielectric layer 57. For example, the dielectric layer 112 includes SiN and the dielectric layer 114 includes SiO₂, or the dielectric layers 112, 114 both include SiOC, and the concentrations of carbon in the dielectric layer 112 is greater than that in the dielectric layer 114.

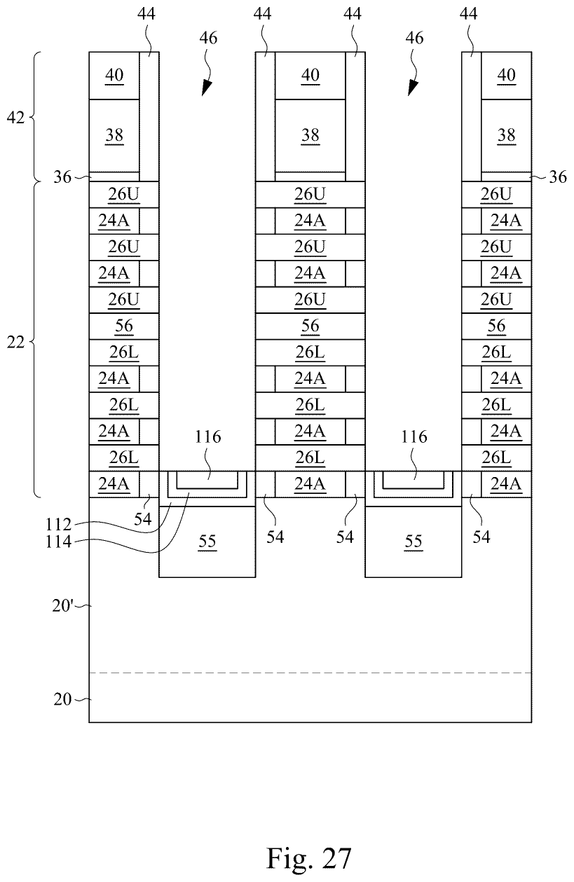

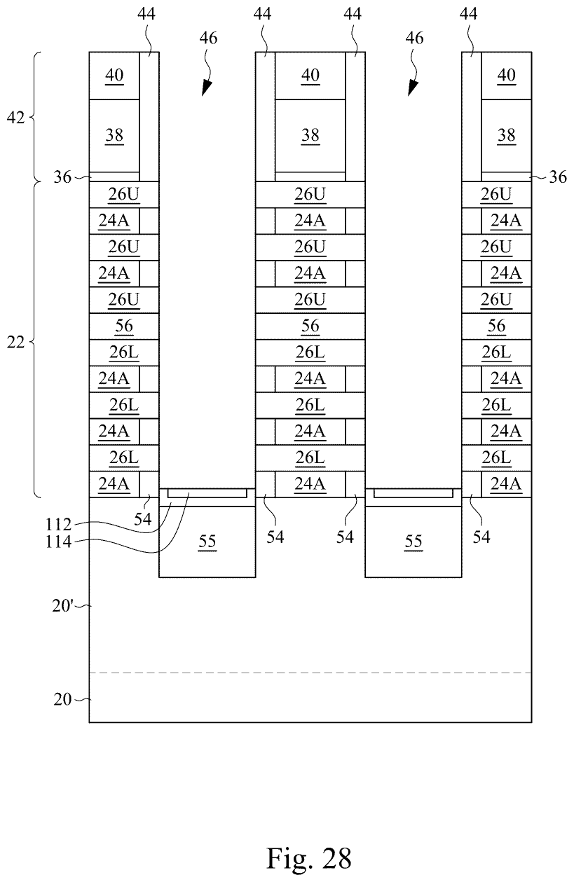

In FIG. 26, a sacrificial layer 116 is formed in the source/drain recess 46. The sacrificial layer 116 may include any material having different etch selectivity compared to the dielectric layers 112, 114. In some embodiments, the sacrificial layer 116 is a bottom anti-reflective coating (BARC). The sacrificial layer 116 may initially fill the source/drain recess 46, and an etch back process is performed to recess the sacrificial layer 116. Next, as shown in FIG. 27, the portions of the first and second dielectric layers 112, 114 not covered by the sacrificial layer 116 are removed. In some embodiments, the portions of the first and second dielectric layers 112, 114 are removed by a wet etch process. Then, the sacrificial layer 116 is removed, as shown in FIG. 28.

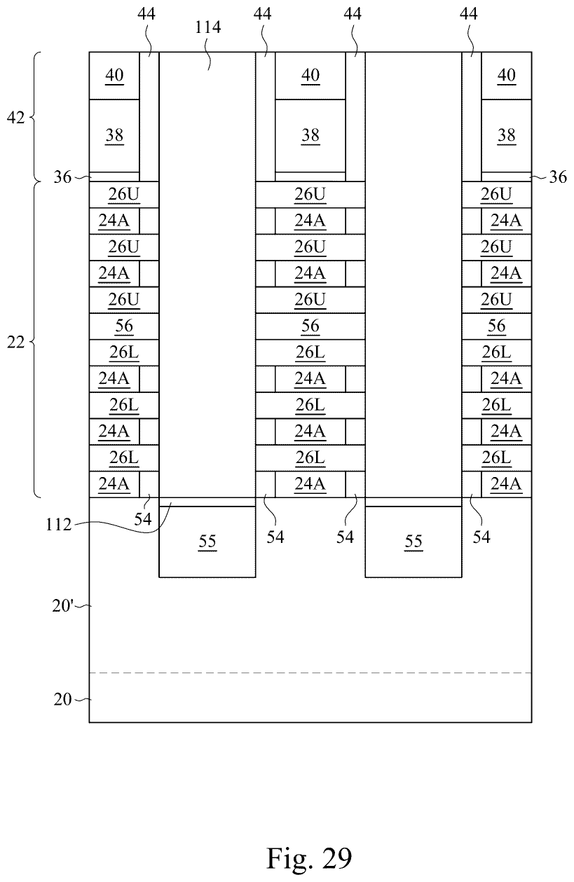

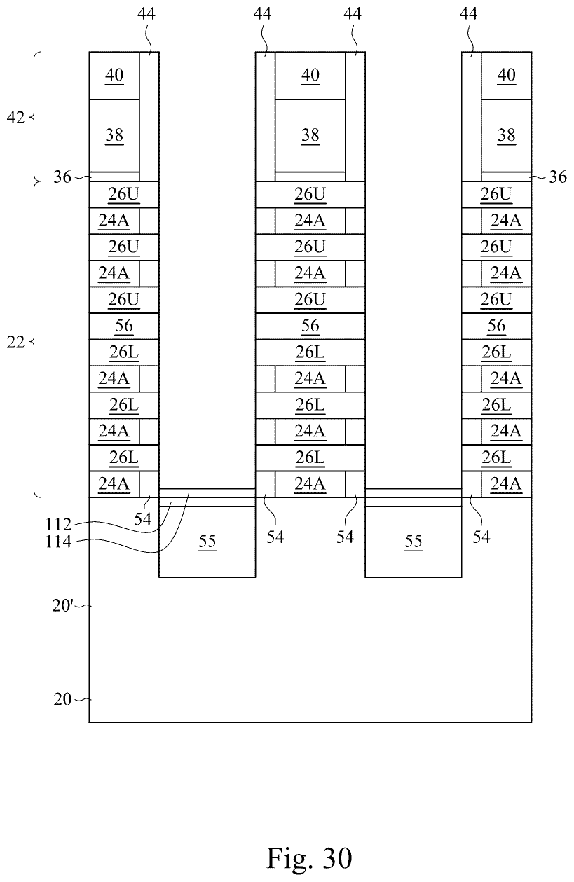

FIGS. 29, 30, and 31 are views of intermediate stages in the manufacturing of a stacking transistor in accordance with alternative embodiments. As shown in FIG. 29, in some embodiments, the first dielectric layer 112 is formed at the bottom of the source/drain recess 46. The first dielectric layer 112 may first fill the source/drain recess 46, and a subsequent etch back process removes a portion of the first dielectric layer 112. Next, the second dielectric layer 114 is formed in the source/drain recess 46, as shown in FIG. 29. The second dielectric layer 114 may be also recessed by an etch back process, as shown in FIG. 30.

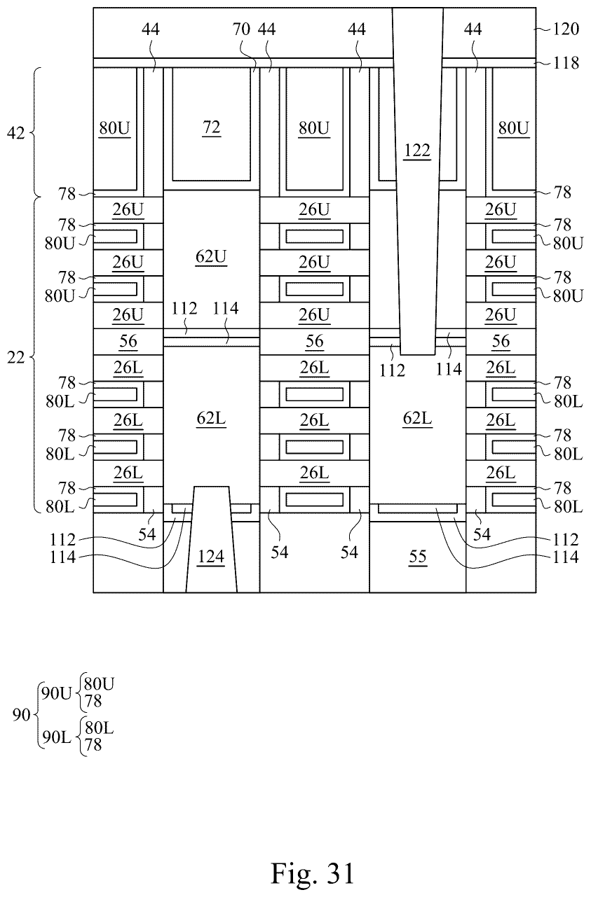

In some embodiments, the first and second dielectric layers 112, 114 may be formed between the semiconductor layer 55 and the lower source/drain regions 62L, as shown in FIG. 31. The first dielectric layer 112 may be in contact with the semiconductor layer 55. The first and second dielectric layers 112, 114 may be also formed between the lower source/drain regions 62L and the upper source/drain regions 62U, as shown in FIG. 31. In some embodiments, after forming the gate stacks 90, an etch stop layer 118 is formed on the gate stacks 90 and the ILD 72, and another ILD 120 is formed on the etch stop layer 118. The etch stop layer 118 may include the same material as the CESL 70, and the ILD 120 may include the same material as the ILD 72. In some embodiments, the thickness of the ILD 72 is greater than the thickness of the ILD 120. An opening (not shown) is formed in the ILD 120, the etch stop layer 118, the ILD 72, the CESL 70, the upper source/drain region 6UL, the first dielectric layer 112, and the second dielectric layer 114 to expose the lower source/drain region 62L, and a conductive feature 122 is formed in the opening. As described above, the first dielectric layer 112 has a slower etch rate compared to the second dielectric layer 114, so the first dielectric layer 112 can function as an etch stop layer during the formation of the opening. The second dielectric layer 114 has a lower k-value than that of the first dielectric layer 112, and parasitic capacitance may be reduced due to the lower k-value.

Similarly, an opening (not shown) may be formed in the semiconductor layer 55, the first dielectric layer 112, and the second dielectric layer 114 to expose the lower source/drain regions 62L during backside processing, and a conductive feature 124 is formed in the opening. During the formation of the opening, the first dielectric layer 112 can function as an etch stop layer. Thus, in some embodiments, the second dielectric layer 114 is disposed on the first dielectric layer 112 when the first and second dielectric layers 112, 114 are disposed between the semiconductor layer 55 and the lower source/drain region 62L, and the first dielectric layer 112 is disposed on the second dielectric layer 114 when the first and second dielectric layers 112, 114 are disposed between the lower source/drain regions 62L and the upper source/drain regions 62U.

The first and second dielectric layers 112, 114 may be mixed and matched with the dielectric layers described above in the stacking transistor 10 to prevent current leakage, prevent over etching of the source/drain region, prevent air gap formation, and/or to function as an etch stop layer without increasing parasitic capacitance.

An embodiment is a semiconductor device structure. The structure includes an isolation region extending over a substrate and an interlayer dielectric (ILD) disposed over the isolation region. Each of the isolation region and the ILD has a k-value that is about 3 to about 5. The structure further includes an etch stop layer disposed between the ILD and the isolation region, a plurality of semiconductor nanostructures disposed adjacent to the isolation region, and a gate stack surrounding each of the semiconductor nanostructures. The gate stack includes a gate dielectric and a gate electrode over the gate dielectric. The structure further includes a gate spacer extending along a sidewall of the gate stack, and a k-value of the gate dielectric is greater than a k-value of the gate spacer. The structure further includes a first source/drain region electrically connected to a first semiconductor nanostructure of the plurality of semiconductor nanostructures, a semiconductor layer disposed below the first source/drain region, and a first dielectric layer disposed between the first source/drain region and the semiconductor layer. The first dielectric layer includes a first top surface that is concave and a first bottom surface that is substantial flat.

Another embodiment is a semiconductor device structure. The structure includes an isolation region extending over a substrate and an interlayer dielectric (ILD) disposed over the isolation region. Each of the isolation region and the ILD has a k-value that is about 3 to about 5. The structure further includes an etch stop layer disposed between the ILD and the isolation region, a plurality of semiconductor nanostructures disposed adjacent the isolation region, and a gate stack surrounding each of the semiconductor nanostructures. The gate stack includes a gate dielectric and a gate electrode over the gate dielectric. The structure further includes a gate spacer extending along a sidewall of the gate stack, and a k-value of the gate dielectric is greater than a k-value of the gate spacer. The structure further includes a first source/drain region electrically connected to a first semiconductor nanostructure of the plurality of semiconductor nanostructures, a semiconductor layer disposed below the first source/drain region, and a first dielectric layer disposed between the first source/drain region and the semiconductor layer. The first dielectric layer includes a first top surface that is convex and a first bottom surface that is convex.

A further embodiment is a method. The method includes forming a plurality of semiconductor nanostructures over a substrate, forming a source/drain recess in the plurality of semiconductor nanostructures, depositing a semiconductor layer in the source/drain recess, and depositing a first dielectric layer over the semiconductor layer. The first dielectric layer is formed by a first process. The method further includes depositing a second dielectric layer over the semiconductor layer by a second process different from the first process and performing multiple etch processes on the first and second dielectric layers to form a third dielectric layer on the semiconductor layer. The third dielectric layer has a concave top surface and a flat bottom surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
an isolation region extending over a substrate;
an interlayer dielectric (ILD) disposed over the isolation region, wherein each of the isolation region and the ILD has a k-value that is about 3 to about 5;
an etch stop layer disposed between the ILD and the isolation region;
a plurality of semiconductor nanostructures disposed adjacent to the isolation region;
a gate stack surrounding each of the semiconductor nanostructures, wherein the gate stack comprises a gate dielectric and a gate electrode over the gate dielectric;
a gate spacer extending along a sidewall of the gate stack, wherein a k-value of the gate dielectric is greater than a k-value of the gate spacer;
a first source/drain region electrically connected to a first semiconductor nanostructure of the plurality of semiconductor nanostructures;
a semiconductor layer disposed below the first source/drain region; and
a first dielectric layer disposed between the first source/drain region and the semiconductor layer, wherein the first dielectric layer comprises a first top surface that is concave and a first bottom surface that is substantial flat.

2. The semiconductor device structure of claim 1, further comprising a second source/drain region disposed over the first source/drain region, wherein the second source/drain region is electrically connected to a second semiconductor nanostructure of the plurality of semiconductor nanostructures.

3. The semiconductor device structure of claim 2, further comprising a second dielectric layer disposed between the first and second source/drain regions.

4. The semiconductor device structure of claim 3, wherein the second dielectric layer comprises a second top surface and a second bottom surface.

5. The semiconductor device structure of claim 4, wherein the first and second top surfaces have different shapes, and the first and second bottom surfaces have different shapes.

6. The semiconductor device structure of claim 4, wherein the first and second top surfaces have the same shape, and the first and second bottom surfaces have the same shape.

7. The semiconductor device structure of claim 4, wherein the second top surface is convex, and the second bottom surface is convex.

8. The semiconductor device structure of claim 3, further comprising a third dielectric layer disposed between the first and second semiconductor nanostructures of the plurality of semiconductor nanostructures.

9. The semiconductor device structure of claim 8, wherein a height of the second dielectric layer is within a height of the third dielectric layer.

10. A semiconductor device structure, comprising:
an isolation region extending over a substrate;
an interlayer dielectric (ILD) disposed over the isolation region, wherein each of the isolation region and the ILD has a k-value that is about 3 to about 5;
an etch stop layer disposed between the ILD and the isolation region;
a plurality of semiconductor nanostructures disposed adjacent the isolation region;
a gate stack surrounding each of the semiconductor nanostructures, wherein the gate stack comprises a gate dielectric and a gate electrode over the gate dielectric;
a gate spacer extending along a sidewall of the gate stack, wherein a k-value of the gate dielectric is greater than a k-value of the gate spacer;
a first source/drain region electrically connected to a first semiconductor nanostructure of the plurality of semiconductor nanostructures;
a semiconductor layer disposed below the first source/drain region; and
a first dielectric layer disposed between the first source/drain region and the semiconductor layer, wherein the first dielectric layer comprises a first top surface that is convex and a first bottom surface that is convex.

11. The semiconductor device structure of claim 10, wherein the first source/drain region has a second top surface and a second bottom surface that is concave.

12. The semiconductor device structure of claim 11, wherein the second top surface is flat.

13. The semiconductor device structure of claim 11, wherein the second top surface is concave.

14. The semiconductor device structure of claim 11, wherein the second top surface is convex.

15. The semiconductor device structure of claim 11, further comprising a second source/drain region disposed on the second dielectric layer.

16. A method for forming a semiconductor device structure, comprising:
forming a plurality of semiconductor nanostructures over a substrate;
forming a source/drain recess in the plurality of semiconductor nanostructures;
depositing a semiconductor layer in the source/drain recess;
depositing a first dielectric layer over the semiconductor layer, wherein the first dielectric layer is formed by a first process;
depositing a second dielectric layer over the semiconductor layer by a second process different from the first process; and
performing multiple etch processes on the first and second dielectric layers to form a third dielectric layer on the semiconductor layer, wherein the third dielectric layer has a concave top surface and a flat bottom surface.

17. The method of claim 16, wherein the first and second dielectric layers comprises a same material, and a height of the first dielectric layer is greater than a height of the second dielectric layer.

18. The method of claim 16, wherein the first and second dielectric layers comprises different materials, and a height of the first dielectric layer is less than a height of the second dielectric layer.

19. The method of claim 16, wherein the first process is a flowable chemical vapor deposition process, and the second process is an atomic layer deposition process.

20. The method of claim 19, wherein the multiple etch processes comprises at least an anisotropic etch process and an isotropic etch process.
